(19) United States
(12) Patent Application Publication
(10) Pub. No.: US 2018/0148832 A1
(43) Pub. Date: May 31, 2018

(54) METHODS FOR DEPOSITING FLOWABLE CARBON FILMS USING HOT WIRE CHEMICAL VAPOR DEPOSITION

(71) Applicant: APPLIED MATERIALS, INC., Santa Clara, CA (US)

(72) Inventors: Sukti CHATTERJEE, Cupertino, CA (US); LANCE SCUDDER, Sunnyvale, CA (US); ERIC H. LIU, San Mateo, CA (US); PRAVIN K. NARWANKAR, Sunnyvale, CA (US); PRAMIT MANNA, Milpitas, CA (US); ABHIJIT MALLICK, Fremont, CA (US)

(21) Appl. No.: 15/800,249

(22) Filed: Nov. 1, 2017

Related U.S. Application Data
(60) Provisional application No. 62/426,385, filed on Nov. 25, 2016.

(51) Int. Cl. C23C 16/26; C23C 16/48; H01L 21/02

(52) U.S. Cl. CPC C23C 16/26; H01L 21/02205; H01L 21/02118; C23C 16/48

(57) ABSTRACT

In some embodiments, a method of processing a substrate disposed within a processing volume of a hot wire chemical vapor deposition (HWCVD) process chamber, includes: (a) providing a carbon containing precursor gas into the processing volume, the carbon containing precursor gas being provided into the processing volume from an inlet located a first distance above a surface of the substrate; (b) breaking hydrogen-carbon bonds within molecules of the carbon containing precursor via introduction of hydrogen radicals to the processing volume to deposit a flowable carbon layer atop the substrate, wherein the hydrogen radicals are formed by flowing a hydrogen containing gas over a plurality of filaments disposed within the processing volume above the substrate and the inlet.

### CROSS-REFERENCE TO RELATED APPLICATIONS

This application claims the benefit of U.S. provisional application Ser. No. 62/426,385, filed Nov. 25, 2016, which is herein incorporated by reference in its entirety.

### FIELD

Embodiments of the present disclosure generally relate to methods for flowable carbon films.

### BACKGROUND

Flowable carbon films are often used in semiconductor manufacturing process to provide void free gap fills, low shrinkage rates, high modulus, and high etch selectivity. Flowable carbon films are typically formed using a remote plasma system. Remote plasmas (e.g., a plasma formed outside of the processing chamber) and quasi-remote plasmas (e.g., a plasma formed within the same process chamber as the substrate at a distance from the substrate) form ions that can damage the surface of the substrate.

Therefore, the inventors have provided improved methods for depositing flowable carbon films.

### SUMMARY

Methods for depositing materials on substrates in a hot wire chemical vapor deposition (HWCVD) process are provided herein. In some embodiments, a method of processing a substrate disposed within a processing volume of a hot wire chemical vapor deposition (HWCVD) process chamber includes: (a) providing a carbon containing precursor gas into the processing volume, the carbon containing precursor gas being provided into the processing volume from an inlet located a first distance above a surface of the substrate; (b) breaking hydrogen- carbon bonds within molecules of the carbon containing precursor via introduction of hydrogen radicals to the processing volume to deposit a flowable carbon layer atop the substrate, the hydrogen radicals being formed by flowing a hydrogen containing gas over a plurality of filaments disposed within the processing volume above the substrate and the inlet.

In some embodiments, the disclosure may be embodied in a computer readable medium having instructions stored thereon that, when executed, cause a method to be performed in a process chamber, the method includes any of the embodiments disclosed herein.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are not to be considered limiting of scope, for the disclosure may admit to other equally effective embodiments.

FIG. 1 depicts a flow chart for a method of depositing flowable carbon films in accordance with some embodiments of the present disclosure.

FIG. 2 depicts a schematic side view of a HWCVD process chamber in accordance with some embodiments of the present disclosure.

FIG. 3 shows the reaction process 300 for forming a flowable carbon layer using a carbon containing precursor in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of the present disclosure provide hot wire chemical vapor deposition (HWCVD) processing techniques useful for depositing flowable carbon films. In one exemplary application, embodiments of the present disclosure may advantageously be used to deposit flowable carbon films without ion bombardment on the substrate. Embodiments of the present disclosure may advantageously be used to deposit flowable carbon films via a hot wire chemical vapor deposition (HWCVD) process chamber for providing a higher concentration of hydrogen radicals to deposit the flowable carbon films compared with remote plasma systems. Embodiments of the present disclosure may also advantageously be used to deposit flowable carbon films via a hot wire chemical vapor deposition (HWCVD) process chamber for providing hydrogen radicals that can be used to cure the flowable carbon films without additional curing energy, such as via application of ultraviolet (UV) light energy. Embodiments of the present disclosure may advantageously be used to convert thicker layer deposition into a cyclic process involving a plurality of thin deposition layers followed by an in-situ hydrogen radical annealing. Embodiments of the present disclosure may improve the densification of thicker layers. Embodiments of the present disclosure may improve the densification of high aspect ratio pattern fills.

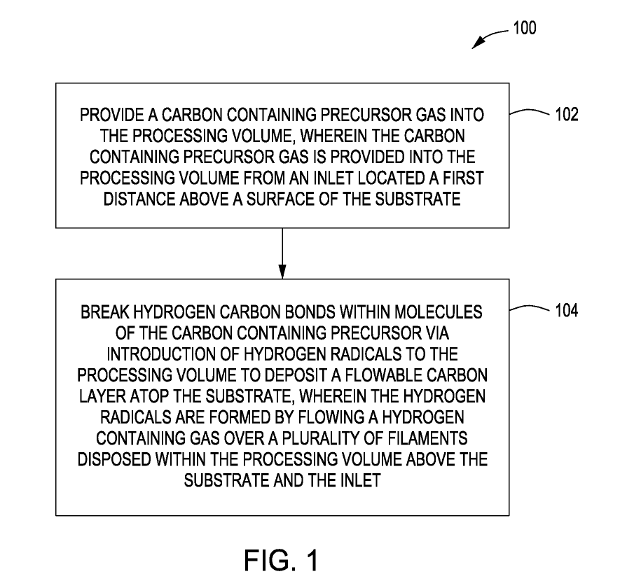

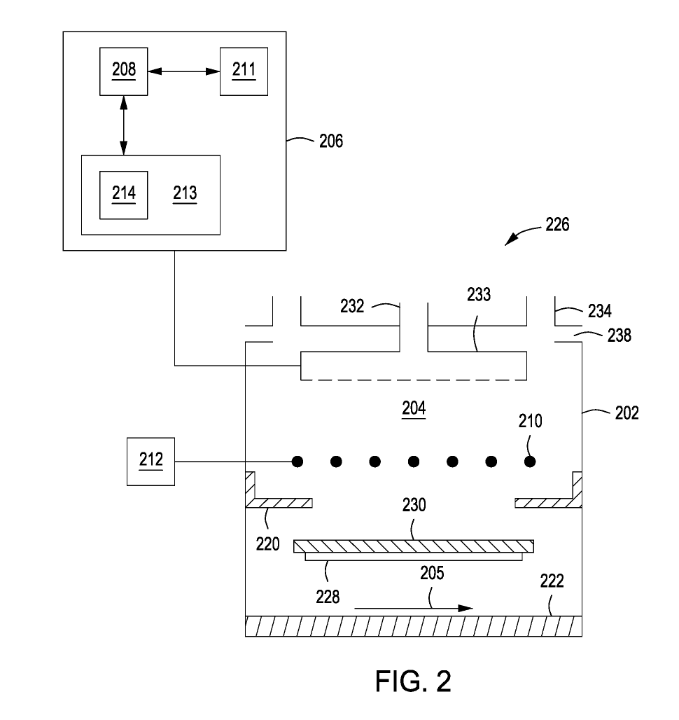

FIG. 1 depicts a flow chart for a method 100 of depositing flowable carbon films atop a substrate in a hot wire chemical vapor deposition (HWCVD) process chamber. FIG. 2 depicts a schematic side view of an illustrative substrate processing system used to perform the method of FIG. 1 in accordance with some embodiments of the present disclosure.

The method 100 begins at 102 by providing a carbon containing precursor gas into the processing volume, the carbon containing precursor gas being provided into the processing volume from an inlet located a first distance above a surface of the substrate.

The substrate may be any suitable substrate, such as a silicon substrate, a III-V compound substrate, a silicon germanium (SiGe) substrate, an epi-substrate, a silicon-on-insulator (SOI) substrate, a display substrate such as a liquid crystal display (LCD), a plasma display, an electro luminescence (EL) lamp display, a light emitting diode (LED) substrate, a solar cell array, solar panel, or the like. In some embodiments, the substrate may be a semiconductor wafer (e.g., a 200 mm, a 300 mm, or the like, silicon wafer). In some embodiments, the substrate may include additional semiconductor manufacturing process layers, such as dielectric layers, metal layers, and the like. In some embodiments, the substrate may be a partially fabricated semiconductor device such as Logic, DRAM, or a Flash memory device. In addition, features, such as trenches, vias, or the like, may be formed in one or more layers of the substrate.

The carbon containing precursor gas provided to the processing volume is, in some embodiments, at least one of an alkane having the general chemical formula CnH2n+2. Examples of alkanes are, but not limited to, methane, ethane, propane, butane, pentane, hexane, heptane, or octane. In some embodiments, the carbon containing precursor gas is an alkene (e.g., an unsaturated hydrocarbon that contains at least one carbon—carbon double bond). Examples of alkenes are, but not limited to, ethylene, propene, butene, hexene, heptene, or octene. In some embodiments, the carbon containing precursor gas is an alkyne (e.g., an unsaturated hydrocarbon containing at least one carbon—carbon triple bond). Examples of alkynes are, but not limited to, acetylene, ethyne, propyne, butyne, hexyne, heptyne, or octyne. In some embodiments, the carbon containing precursor gas provided to the processing volume is an aromatic hydrocarbon. Examples of aromatic hydrocarbons are, but not limited to, benzenes, toluenes, xylenes, mesitylenes, phenols, anisoles, cresols, furans, anilines, pyridines, pyrroles, ketones, imines, or aromatic esters. The flow rate of the carbon containing precursor gas is optionally adjusted based on process chamber designs. For example, surface areas of flowable film deposition, film growth rates, chamber operating pressures, and/or flux of radical initiator gas source or any combination thereof, etc., may be adjusted. The flow rate of the carbon containing precursor gas is, for example, about 100 to about 1000 mg/min.

Formation of a flowable carbon film may depend on the temperature of the substrate during the deposition process and/or the distance (i.e., a first distance) above the substrate surface that the carbon containing precursor gas is introduced to the processing volume. A typical temperature of the substrate is about −50 to about 150 degrees Celsius. The carbon containing precursor gas is introduced to the processing volume through an inlet disposed about 10 to about 50 mm above the surface of the substrate.

Next, at 104, hydrogen-carbon bonds within molecules of the carbon containing precursor gas are broken via introduction of hydrogen radicals to the processing volume to deposit a flowable carbon layer atop the substrate, the hydrogen radicals initiating polymerization of the molecules of the carbon containing precursor. As used herein, a flowable carbon film refers to a carbon film that is deposited within a feature on a substrate in a “bottom-up” manner (i.e., the film deposits substantially in all areas and fills the feature from the bottom of the feature to the top of the feature and, advantageously, without forming a void within the film material deposited in the feature.) The flowable carbon film deposited via the method 100 is carbon and/or carbon complexes.

The hydrogen radicals are formed by flowing a hydrogen containing gas over a heated plurality of wires or filaments disposed within the processing volume above or below the substrate and the inlet. The temperature of the heated plurality of wires or filaments is about 1300 to about 2400 degrees Celsius.

In some embodiments, an additional gas(es), for example, Argon and/or Helium, may be delivered to the hydrogen radical processing volume to enhance the purging efficiency of the cavity containing the hot wire filaments. Enhancing the purging efficiency can decrease back diffusion of reactive species, which can rapidly degrade the quality of the hot wire filaments.

In some embodiments, the hydrogen containing gas is hydrogen (H₂) gas, ammonia (NH₃) gas, or one or more combinations thereof. In some embodiments, where the hydrogen containing gas is ammonia (NH₃) gas or a combination of ammonia (NH₃) gas and hydrogen (H₂) gas, the hydrogen-carbon bonds within molecules of the carbon containing precursor gas are broken via introduction of hydrogen radicals and ammonia (NH₃) radicals to the processing volume. The flow rate of the hydrogen containing gas is about 1 to about 10000 standard cubic centimeters per minute (sccm).

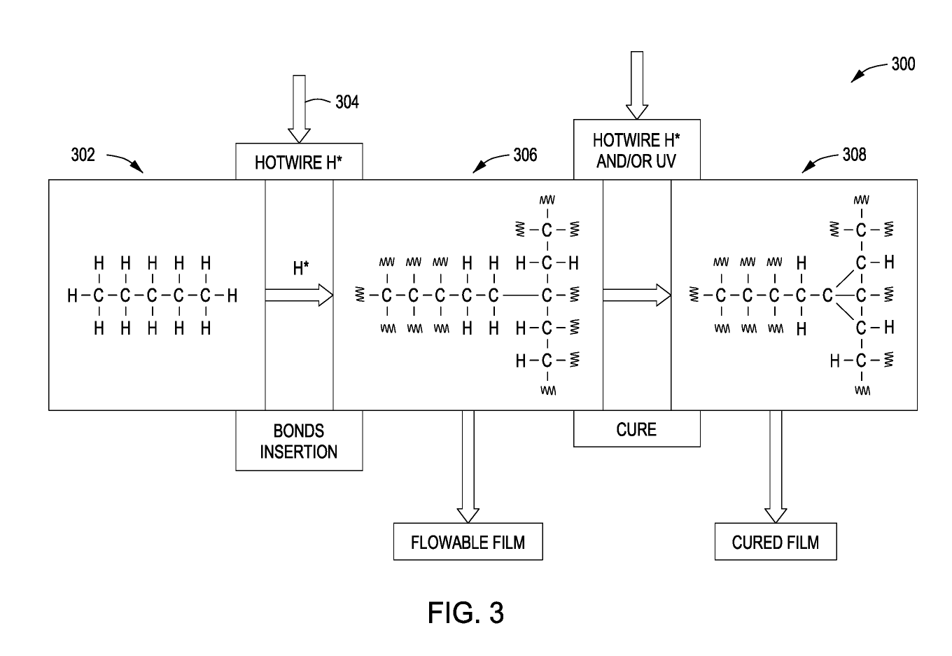

FIG. 3 shows the reaction process 300 for forming a flowable carbon layer using a carbon containing precursor, such as any of alkanes, alkenes, alkynes, and/or aromatic hydrocarbons and/or mixtures thereof described above. The carbon containing precursor 302 is exposed to hydrogen radicals 304 from a hotwire source. The energy of the hydrogen radicals breaks the hydrogen-carbon bonds in the carbon containing precursor 302 resulting in flowable carbon film 306. As discussed further below, the flowable carbon film 306 can be cured via the energy of the hydrogen radicals. In some embodiments, the flowable carbon film 306 can be cured via the energy of the hydrogen radicals and/or exposure to UV light to form a cured carbon film 308.

The flowable carbon layer can be cured after depositing the flowable carbon layer. In some embodiments, the application of only UV light to the flowable carbon layer cures the flowable carbon layer. For example, in some embodiments, curing of the flowable carbon layer occurs with a chamber pressure of 0.5-2000 torr and an exposure time of one to thirty minutes of ambient Argon (Ar) at about 100-1000 sccm. In some embodiments, the flowable carbon layer is cured via application of hydrogen radical energy. For example, in some embodiments, a hydrogen gas flow of 0.1-10000 sccm, a chamber pressure of 50 millitorr to 5 torr, a filament temperature of 1300-2400° C. and an exposure time of about 10-600 seconds. In some embodiments, the flowable carbon layer is cured via application of hydrogen radical energy and/or by application of UV light to the flowable carbon layer.

In some embodiments, a first layer of the flowable carbon layer is formed on the substrate. The first layer can have a thickness that is less than the final thickness of the flowable carbon layer. For example, the first layer can have a thickness of about 10 to about 100 angstroms. The first layer can be cured via application of hydrogen radical energy and/or applying UV light to the flowable carbon layer. The process of depositing a first layer and then curing the first layer can be repeated until a flowable carbon layer having a predetermined thickness is formed. In some embodiments, after the flowable carbon layer having a predetermined thickness is formed, the flowable carbon layer having a predetermined thickness can be further cured by applying UV light to the flowable carbon layer having a predetermined thickness.

As described below with respect to FIG. 2, the HWCVD process chamber 226 comprises a plurality of wires 210 or plurality of filaments. The plurality of wires 210 is heated to a temperature suitable to dissociate the hydrogen gas, producing hydrogen ions that react with the carbon containing precursor gas and deposit a flowable carbon layer atop the substrate 230. For example, the plurality of wires 210 may be heated to a temperature of about 1300 to about 2400 degrees Celsius.

FIG. 2 depicts a schematic side view of an HWCVD process chamber 226 (i.e., process chamber 226) suitable for use in accordance with embodiments of the present disclosure. The process chamber 226 generally comprises a chamber body 202 having an internal processing volume 204. The plurality of wires 210 are disposed within the chamber body 202 (e.g., within the internal processing volume 204). The plurality of wires 210 may also be a single wire routed back and forth across the internal processing volume 204. The plurality of wires 210 comprises a HWCVD source. The plurality of wires 210 are typically made of tungsten. Other high temperature materials may be used instead of tungsten. Suitable alternative materials include tantalum, iridium, tantalum carbide, hafnium carbide, and tantalum hafnium carbide. Some embodiments include a coating disposed on the plurality of wires 210. Some coating materials include tantalum, iridium, tantalum carbide, and hafnium carbide disposed on tungsten wires. The plurality of wires 210 are clamped in place by support structures (not shown) to keep the wires taut when heated to high temperatures, and to provide electrical contact to the wire. In some embodiments, wire tensioners are used to allow the wire to remain taut through various heating and cooling cycles that might otherwise allow an untensioned wire to sag because of thermal expansion and plastic deformation. A power supply 212 is coupled to the plurality of wires 210 to provide current to heat the plurality of wires 210. A substrate 230 may be positioned under the HWCVD source (e.g., the plurality of wires 210), for example, on a substrate support 228. The substrate support 228 may be stationary for static deposition, or may rotate and/or move linearly (as shown by arrow 205) for dynamic deposition as the substrate 230 passes under the HWCVD source.

The chamber body 202 further includes one or more gas inlets (one gas inlet 232 shown) to provide one or more process gases and one or more outlets (two outlets 234 shown) to a vacuum pump to maintain a suitable operating pressure within the process chamber 226 and to remove excess process gases and/or process byproducts. The gas inlets 232 may feed into a shower head 233 (as shown), or other suitable gas distribution element, to distribute the gas substantially uniformly over the plurality of wires 210 or substrate 230.

In some embodiments, one or more shields 220 may be provided to minimize unwanted deposition on interior surfaces of the chamber body 202. Alternatively or in combination, one or more chamber liners 222 can be used to make cleaning easier. The use of shields, and/or liners, may preclude or reduce the use of unfavorable cleaning gases, such as the greenhouse gas NF₃. The shields 220 and/or chamber liners 222 generally protect the interior surfaces of the chamber body from undesirably collecting deposited materials due to the process gases flowing in the chamber. The shields 220 and chamber liners 222 may be removable, replaceable, and/or cleanable. The shields 220 and chamber liners 222 may be configured to cover every area of the chamber body that could become coated, including but not limited to, around the plurality of wires 210 and on any or all walls of the coating compartment. Typically, the shields 220 and chamber liners 222 may be fabricated from aluminum (Al) and may have a roughened surface to enhance adhesion of deposited materials (to prevent flaking off of deposited material). The shields 220 and chamber liners 222 may be mounted in any or all area(s) of the process chamber, such as around the HWCVD sources, in any suitable manner. In some embodiments, the source, shields, and liners may be removed for maintenance and cleaning by opening an upper portion of the deposition chamber. For example, in some embodiments, a lid, or ceiling, of the deposition chamber may be coupled to the body of the deposition chamber along a flange 238 that supports the lid and provides a surface to secure the lid to the body of the deposition chamber.

A controller 206 may be coupled to various components of the process chamber 226 to control the operation thereof. Although schematically shown coupled to the process chamber 226, the controller may be operably connected to any component that may be controlled by the controller, such as the power supply 212, a gas supply (not shown) coupled to the gas inlet 232, a vacuum pump and or throttle valve (not shown) coupled to the outlet 234, the substrate support 228, and the like, in order to control the HWCVD deposition process in accordance with the methods disclosed herein. The controller 206 generally comprises a central processing unit (CPU) 208, a memory 213, and support circuits 211 for the CPU 208. The controller 206 may control the process chamber 226 directly, or via other computers or controllers (not shown) associated with particular support system components. The controller 206 may be one of any form of general-purpose computer processor that can be used in an industrial setting for controlling various chambers and sub-processors. The memory, or computer-readable medium, 213 of the CPU 208 may be one or more of readily available memory such as random access memory (RAM), read only memory (ROM), floppy disk, hard disk, flash, or any other form of digital storage, local or remote. The memory 213 may be a non-transitory computer readable medium having instructions stored thereon that, when executed, cause the process chamber 226 to perform a method of processing a substrate disposed within a processing volume of a hot wire chemical vapor deposition (HWCVD) process chamber, as described herein. The support circuits 211 are coupled to the CPU 208 for supporting the processor in a conventional manner. These circuits include cache, power supplies, clock circuits, input/output circuitry and subsystems, and the like. Inventive methods as described herein may be stored in the memory 213 as software routine 214 that may be executed or invoked to turn the controller into a specific purpose controller to control the operation of the process chamber 226 in the manner described herein. The software routine may also be stored and/or executed by a second CPU (not shown) that is remotely located from the hardware being controlled by the CPU 208.

While the foregoing is directed to embodiments of the present disclosure, other and further embodiments of the disclosure may be devised without departing from the basic scope thereof.

1. A method of processing a substrate disposed within a processing volume of a hot wire chemical vapor deposition (HWCVD) process chamber, comprising:
(a) providing a carbon containing precursor gas into the processing volume, the carbon containing precursor gas being provided into the processing volume from an inlet located a first distance above or below a surface of the substrate; and
(b) breaking hydrogen-carbon bonds within molecules of the carbon containing precursor via introduction of hydrogen radicals to the processing volume to deposit a flowable carbon layer atop the substrate, wherein the hydrogen radicals are formed by flowing a hydrogen containing gas over a plurality of wires or filaments disposed within the processing volume above or below the substrate and the inlet.

2. The method of claim 1, wherein the carbon containing precursor gas is at least one of an alkane, an alkene, an alkyne, or an aromatic hydrocarbon.

3. The method of claim 2, wherein the alkane is methane, ethane, propane, butane, pentane, hexane, heptane, or octane, the alkene is one of ethylene, propene, butene, hexene, heptene, or octene, the alkyne is one of acetylene, ethyne, propyne, butyne, hexyne, heptyne, or octyne, and the aromatic hydrocarbon is one of benzene, toluene, xylene, mesitylene, phenol, anisole, cresol, furan, aniline, pyridine, pyrrole, a ketone, an imine, or an aromatic ester.

4. The method of claim 1, wherein the first distance is about 10 to about 50 mm above the surface of the substrate.

5. The method of claim 1, wherein a temperature of the substrate is about 50 to about 150 degrees Celsius.

6. The method of claim 1, wherein a temperature of the plurality of wires or filaments is about 1300 to about 2400 degrees Celsius.

7. The method of claim 1, wherein a flow rate of the hydrogen containing gas is about 0.1 to about 10000 sccm.

8. The method of claim 1, wherein a flow rate of the carbon containing precursor gas is about 1 to about 1000 mg/min.

9. The method of claim 1, further comprising, curing the flowable carbon layer after depositing the flowable carbon layer.

10. The method of claim 9, further comprising applying UV light to the flowable carbon layer to cure the flowable carbon layer.

11. The method of claim 9, further comprising curing the flowable carbon layer via application of hydrogen radical energy.

12. The method of claim 9, further comprising curing the flowable carbon layer via application of hydrogen radical energy and/or applying UV light to the flowable carbon layer.

13. The method of claim 1, further comprising:
(c) depositing a first layer of the flowable carbon layer;
(d) curing the first layer of the flowable carbon layer via application of hydrogen radical energy followed by applying UV light to the flowable carbon layer; and
(e) repeating (c)-(d) to deposit the flowable carbon layer to a predetermined thickness.

14. The method of claim 13, further comprising:
(f) curing the flowable carbon layer deposited to a predetermined thickness via application of UV light.

15. The method of claim 13, further comprising:
(f) curing the first layer of the flowable carbon layer via application of UV light prior to repeating (c), (d), and (f).

16. A method of processing a substrate disposed within a processing volume of a hot wire chemical vapor deposition (HWCVD) process chamber, comprising:
(a) providing a carbon containing precursor gas into the processing volume, the carbon containing precursor gas being provided into the processing volume from an inlet located a first distance above or below a surface of the substrate; and
(b) breaking hydrogen-carbon bonds within molecules of the carbon containing precursor via introduction of hydrogen radicals to the processing volume to deposit a flowable carbon layer atop the substrate, wherein the hydrogen radicals are formed by flowing a hydrogen containing gas over a plurality of wires or filaments disposed within the processing volume above or below the substrate and the inlet;
(c) depositing a first layer of the flowable carbon layer;
(d) curing the first layer of the flowable carbon layer via application of hydrogen radical energy and/or applying UV light to the flowable carbon layer; and
(e) repeating (c)-(d) to deposit the flowable carbon layer to a predetermined thickness.

17. The method of claim 16, further comprising (f) curing the flowable carbon layer deposited to a predetermined thickness via application of UV light.

18. The method of claim 16, wherein the carbon containing precursor gas further comprises at least one of methane, ethane, propane, butane, pentane, hexane, heptane, or octane, ethylene, propene, butene, hexene, heptene, or octene, acetylene, ethyne, propyne, butyne, hexyne, heptyne, or octyne, benzene, toluene, xylene, mesitylene, phenol, anisole, cresol, furan, aniline, pyridine, pyrrole, a ketone, an imine, or an aromatic ester.

19. A non-transitory computer readable medium, having instructions stored thereon that, when executed, cause a process chamber to perform a method of processing a substrate disposed within a processing volume of a hot wire chemical vapor deposition (HWCVD) process chamber, the method comprising:
(a) providing a carbon containing precursor gas into the processing volume, wherein the carbon containing precursor gas is provided into the processing volume from an inlet located a first distance above or below a surface of the substrate; and
(b) breaking hydrogen-carbon bonds within molecules of the carbon containing precursor via introduction of hydrogen radicals to the processing volume to deposit a flowable carbon layer atop the substrate, wherein the hydrogen radicals are formed by flowing a hydrogen containing gas over a plurality of filaments disposed within the processing volume above or below the substrate and the inlet.

20. The non-transitory computer readable medium of claim 19, wherein the carbon containing precursor gas is an alkane, alkene, alkyne, imine, or aromatic hydrocarbon.
